(19) United States
(12) Patent Application Publication
(10) Pub. No.: US 2015/0072503 A1
(43) Pub. Date: Mar. 12, 2015

(54) METHOD OF MANUFACTURING SEMICONDUCTOR DEVICE

(71) Applicant: KABUSHIKI KAISHA TOSHIBA, TOKYO (JP)

(72) Inventor: Tomoyuki Iguchi, Ishikawa-ken (JP)

(73) Assignee: KABUSHIKI KAISHA TOSHIBA, TOKYO (JP)

(21) Appl. No.: 14/202,697

(22) Filed: Mar. 10, 2014

(30) Foreign Application Priority Data
Sep. 10, 2013 (JP) 2013-187509

(51) Int. Cl. H01L 21/306; H01L 21/762

(52) U.S. Cl. CPC H01L 21/30604; H01L 21/76224
USPC 438/430; 438/706

(57) ABSTRACT

According to one embodiment, a method of manufacturing a semiconductor device includes dry-etching a member containing silicon in a first pressure range equal to or more than a first pressure or in a second pressure range equal to or less than a second pressure, wherein the first pressure is obtained by multiplying a saturated pressure by 0.85, the saturated pressure is defined as a pressure under which an etching rate is one of a maximum value or a value obtained by multiplying the maximum value by a predetermined coefficient, and the etching rate is a half value of the maximum value under the second pressure.

### CROSS-REFERENCE TO RELATED APPLICATION

This application is based upon and claims the benefit of priority from Japanese Patent Application No. 2013-187509, filed Sep. 10, 2013; the entire contents of which are incorporated herein by reference.

### FIELD

Embodiments described herein relate generally to a method of manufacturing a semiconductor device.

### BACKGROUND

A silicon member whose main component is silicon is widely used as a semiconductor device. The silicon member such as a silicon wafer is processed by dry etching in many cases. However, in dry etching, etching rates vary in a surface of the wafer, and as the etching rates vary, the shape of the silicon wafer after the processing varies. As a result, characteristics of the semiconductor devices vary or the productivity is decreased.

### DESCRIPTION OF THE DRAWINGS

FIG. 1 is a flowchart illustrating a method of processing a silicon member in an embodiment;

FIG. 2 is a diagram illustrating a dry etching apparatus in the embodiment;

FIGS. 3A and 3B are graphs illustrating a relation between a pressure and an etching rate in dry etching to the etching rate, and a relation between the pressure and variation in the dry etching, respectively;

FIGS. 4A and 4B are graphs illustrating a method of determining saturated pressure in a modification example;

FIG. 5 is a graph illustrating a relation between the pressure and the etching rate in a preliminary experiment;

FIG. 6A is a cross-sectional view illustrating a wafer to be evaluated before a main process and FIG. 6B is a cross-sectional view illustrating the wafer to be evaluated after the main process;

FIG. 7 is a plan view illustrating a position in which etching depth is determined in the wafer to be evaluated;

FIG. 8 is a graph illustrating a relation between the pressure and the variation in the main process.

### DETAILED DESCRIPTION

In general, according to one embodiment, According to one embodiment, a method of manufacturing a semiconductor device includes performing dry etching on a member containing silicon in a first pressure range equal to or more than a first pressure or in a second pressure range equal to or less than a second pressure, wherein the first pressure is obtained by multiplying a saturated pressure by 0.85, the saturated pressure is defined as a pressure under which an etching rate is one of a maximum value or a value obtained by multiplying the maximum value by a predetermined coefficient, and the etching rate is a half value of the maximum value under the second pressure.

### Embodiment

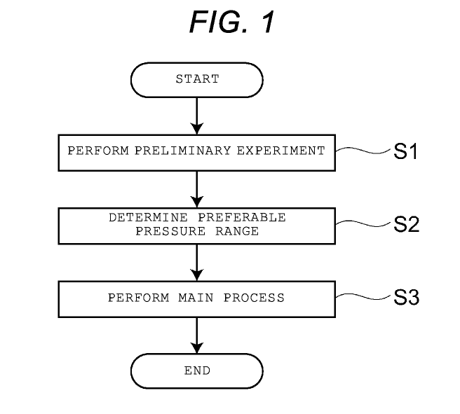

Hereinafter, embodiments will be described with reference to the accompanying drawings. FIG. 1 is a flowchart illustrating an example of a method of processing a silicon member in an embodiment.

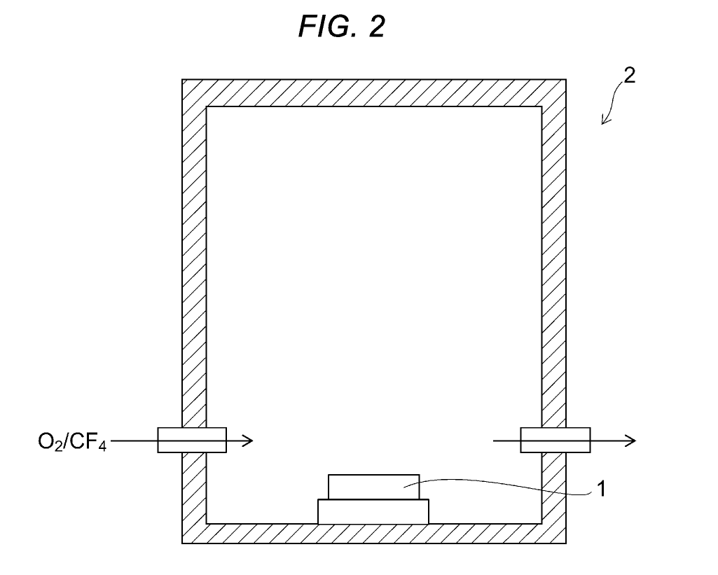

FIG. 2 is a diagram illustrating an example of a dry etching apparatus being used in the embodiment.

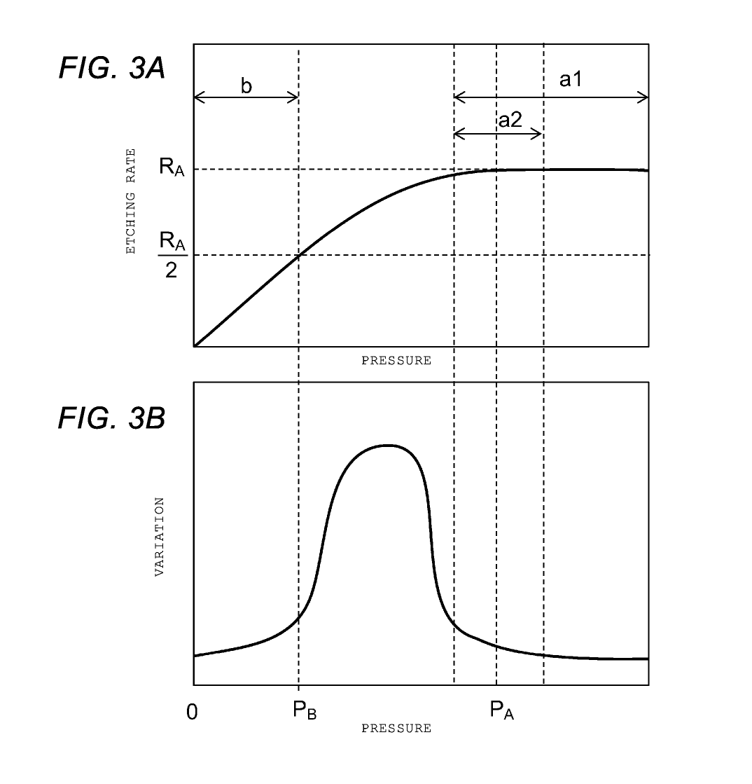

FIG. 3A is a graph illustrating an example of a relation between a pressure and an etching rate in dry etching by setting the transverse axis to the pressure and the longitudinal axis to the etching rate, and FIG. 3B is a graph illustrating an example of a relation between the pressure and variation in dry etching by setting the transverse axis to the pressure and the longitudinal axis to the variation in dimension after the etching processing. In addition, the scale of the pressure is common between of FIG. 3A and FIG. 3B.

The present embodiment relates to a method of manufacturing a semiconductor device by processing a silicon member by dry etching. According to the investigation, two pressure ranges in which variation in the etching processing becomes relatively small are present in dry etching for the silicon member. In the present embodiment, a preliminary experiment is firstly performed as shown in Step S1 of FIG. 1. Further, as shown in Step S2, a preferable pressure range is determined based on the result of the preliminary experiment. Subsequently, as shown in Step S3, a main process is performed on the silicon member using the preferable pressure range.

Firstly, the silicon member as a target to be processed in the present embodiment and a dry etching apparatus being used in the present embodiment will be described. As shown in FIG. 2, dry etching is performed on a silicon member 1 using a dry etching apparatus 2 in the present embodiment. The silicon member 1 is a member including silicon. The silicon member 1 may be, for example, a single crystal silicon wafer, a poly-crystalline silicon film formed on a silicon wafer, or an amorphous silicon film formed on the silicon wafer. In addition, the silicon member 1 may or may not include impurities such as a donor or an acceptor.

The dry etching apparatus 2 is, for example, a chemical dry etching (CDE) apparatus or a reactive ion etching (RIE) apparatus. The dry etching apparatus 2 uses a mixed gas of oxygen (O₂) and carbon tetrafluoride (CF₄) as an etching gas.

Firstly, the preliminary experiment is performed as shown in Step S1 of FIG. 1. Specifically, dry etching such as CDE or RIE is performed on the silicon member 1 for the preliminary experiment using the dry etching apparatus 2 under plural conditions in which pressures inside a chamber are different from each other and parameters other than the pressure are constant, and the etching rates for the respective conditions are evaluated.

In this way, results as shown in FIG. 3A can be generally obtained. That is, positive correlation is observed between the pressure and the etching rate in a range with a sufficiently low pressure, and the etching rate becomes increased as the pressure is increased. However, the positive correlation is not observed between the pressure and the etching rate in a range with the pressure higher than that of the range described above, and the etching rate does not increase even when the pressure is increased. Accordingly, a saturated pressure P_{A} in which the etching rate does not increase anymore even when the pressure is increased is present at a boundary between these two pressure ranges.

Next, a preferable pressure range is calculated as shown in Step S2 of FIG. 1. As a result of the investigation, the variation in the etching processing in the surface of a wafer becomes relatively small when the pressure of dry etching is set to a value of the peripheral saturated pressure P_{A} and in the pressure range equal to or higher than that as shown in FIG. 3B. Therefore, it is preferable to perform dry etching in the pressure range. Specifically, it is preferable to perform dry etching in a pressure range equal to or more than the pressure which is −15% of the saturated pressure P_{A}, that is, in a pressure range a1 equal to or more than the pressure obtained by multiplying the saturated pressure P_{A} by 0.85. However, since the effect of improving the etching rate and the effect of reducing the variation are saturated even when the pressure is excessively increased, it is more preferable that the pressure is set to equal to or less than +15% of the saturated pressure P_{A}. That is, it is still more preferable to perform dry etching with the pressure in a pressure range a2 within ±15% with respect to the saturated pressure P_{A}.

The variation in the etching processing becomes small in the surface of the wafer in the peripheral saturated pressure and in the pressure range a1 equal to or higher than the pressure P_{A} as described above. The reason described above is assumed that the etching rates of respective portions are determined by a reaction-controlled rate not by a supply-controlled rate of the etching gas since adsorption and dissociation to a reaction surface of an etching gas molecule reach saturation by the pressure being sufficiently high in the entire range in the surface of the wafer.

Further, as shown in FIGS. 3A and 3B, when the etching rate at the time of setting the pressure to the saturated pressure P_{A} is set to R_{A} and the pressure which implements a half of the etching rate (R_{A}/2) is set to a pressure P_{B}, the variation in the etching processing in the surface of the wafer becomes relatively small even when the pressure of dry etching is in the pressure range b equal to or less than the pressure P_{B}. Accordingly, dry etching may be performed using the pressure within the pressure range b.

The variation in the etching processing becomes small in the surface of the wafer within the pressure range b. The reason described above is assumed that directivity of gas molecules becomes substantially constant in the surface of the wafer since the pressure is low and a molecule flow becomes more dominant than a viscous flow in the flow of the etching gas. On the other hand, it is assumed that the variation is easily generated in the range between the pressure range a1 and the pressure range b since the etching rates of respective portions are determined by a supply-controlled rate of the etching gas and the viscous flow becomes dominant in the flow of the etching gas.

Next, the main process is performed as shown in Step S3 of FIG. 1. Dry etching is performed on the silicon member 1 to process the silicon member 1 using the dry etching apparatus 2 as shown in FIG. 2. The aspect of the processing is not particularly limited, but, for example, a structure in which a poly-crystalline silicon film is embedded in a trench is prepared as the silicon member 1 by forming plural trenches on the upper surface of the silicon wafer and forming a silicon oxide film on the inner surface of these trenches to deposit silicon. In addition, the poly-crystalline silicon film embedded in the trench is etched back by dry etching such as CDE or RIE.

At this time, dry etching is performed on the silicon member 1 by setting the pressure of dry etching to be a value within the above-described pressure range a1, more preferably within the pressure range a2, or the pressure range b. Accordingly, it is possible to decrease the variation in the etching rate and make the shape after processing uniform in the surface of the wafer.

According to the present embodiment, a semiconductor device with small variation in shape can be manufactured by setting the pressure in an etching atmosphere to be a value within a predetermined pressure range a1, a2, or b when dry etching is performed on the silicon member.

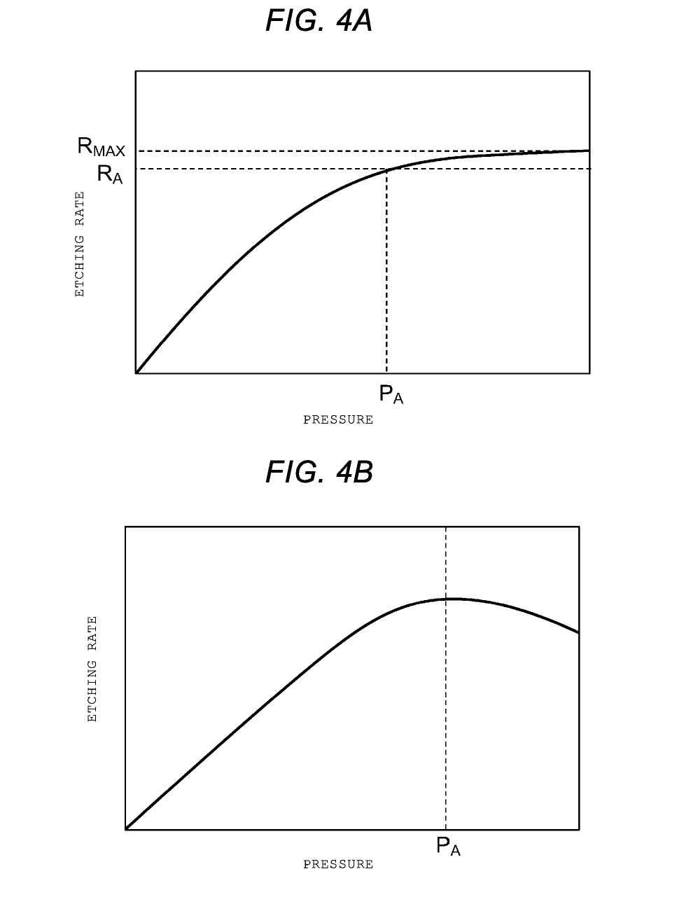

Next, a modification example of a method of determining the saturated pressure P_{A} will be described. FIGS. 4A and 4B are graphs illustrating an example of the method of determining saturated pressure in a modification example by setting the transverse axis to the pressure and the longitudinal axis to the etching rate.

In the example shown in (a) of FIG. 3 described above, the saturated pressure P_{A} is easily determined because a boundary is clearly observed between the one pressure range in which the etching rate has the positive correlation between the pressure and the other pressure range in which the etching rate is not changed even when the pressure is changed is clear. However, practically, such a result may not be obtained all the time. Here, in regard to several patterns, the method of determining the saturated pressure P_{A} will be described.

As shown in FIG. 4A, a case in which the positive correlation is observed between the pressure and the etching rate in the entire range and the saturated pressure P_{A} is necessary to be determined using a suitable approach.

In the case described above, etching rate is steeply increased when the pressure is increased in the low pressure range and the etching rate is gently increased when the pressure is increased in the high pressure range. Therefore, it is possible to set a value obtained by multiplying a maximum value R_{MAX} of the measured etching rate by a predetermined coefficient to an etching rate R_{A}, and the pressure implementing the etching rate R_{A} to the saturated pressure P_{A}. An appropriate value may be selected for the value of the coefficient according to the shape of the curve shown in FIG. 4A, for example, 0.95 may be selected. In other words, an expression of R_{A}=0.95×R_{MAX} may be established.

In addition, as shown in FIG. 4B, a case in which the positive correlation is observed between the pressure and the etching rate in the low pressure range and negative correlation is observed between the pressure and the etching rate in the high pressure range is conceivable. In this case, the pressure whose etching rate is the maximum, that is, a boundary value between the pressure range in which the positive correlation is observed between the pressure and the etching rate and the pressure range in which the negative correlation is observed therebetween may be set to the saturated pressure P_{A}.

### EXAMPLES

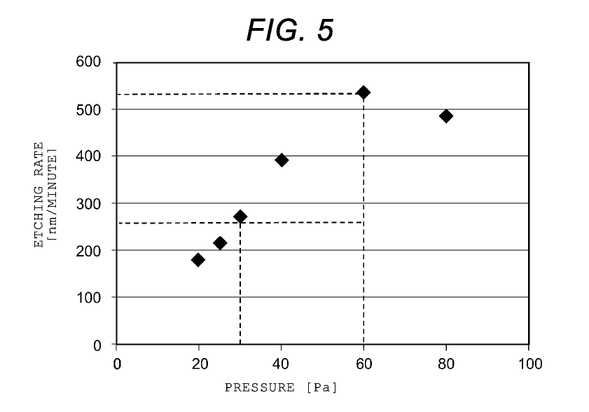

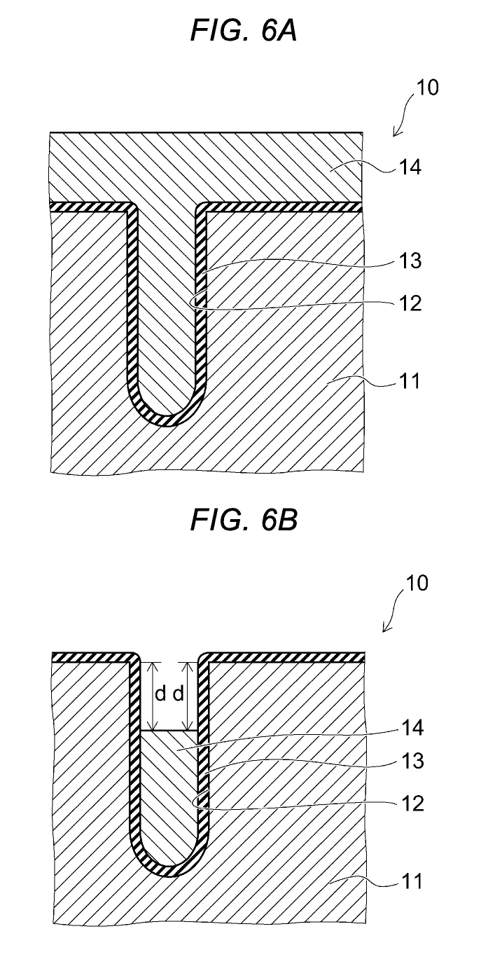

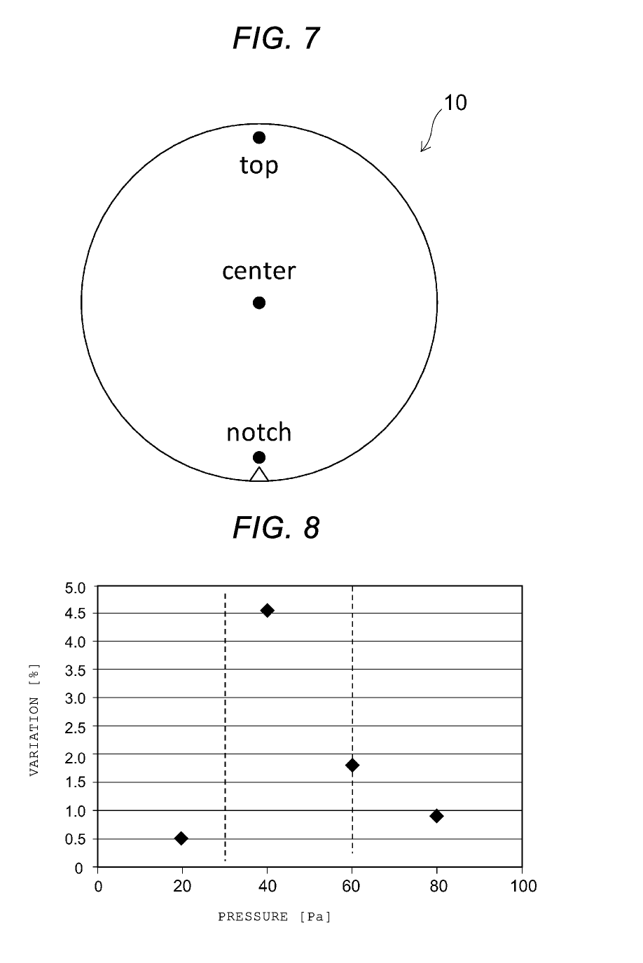

Hereinafter, examples of the present embodiment will be described. FIG. 5 is a graph illustrating a relation between the pressure and the etching rate in a preliminary experiment of an example by setting the transverse axis to the pressure and the longitudinal axis to the etching rate. FIG. 6A is a cross-sectional view illustrating a wafer to be evaluated before a main process of the example and FIG. 6B is a cross-sectional view illustrating the wafer to be evaluated after the main process. FIG. 7 is a plan view illustrating a position in which etching depth is determined in the wafer to be evaluated of the example. FIG. 8 is a graph illustrating an example of a relation between the pressure and the variation in the main process of the example by setting the transverse axis to the pressure and the longitudinal axis to the variation in the dimension after the etching processing.

Firstly, the preliminary experiment is performed as shown in Step S1 of FIG. 1. Specifically, a silicon film containing impurities with a thickness of 800 nm is formed on a silicon wafer by preparing six silicon wafers using a chemical vapor deposition (CVD) method. Subsequently, a desired mark pattern is formed by a lithography process using a photoresist. In this way, six wafers to be evaluated are produced.

Next, the CDE is performed on a silicon film of a wafer to be evaluated 10 under respective conditions by setting six levels of conditions with pressures being different from one another. At this time, a mixed gas of oxygen (O₂) and carbon tetrafluoride (CF₄) is used as an etching gas, and both flow rates of oxygen and carbon tetrafluoride are set to 100 sccm. In addition, the output is set to 600 W and the etching time is set to a time in which the etching amount of the silicon film containing impurities becomes 400 nm. Further, the film thickness of the silicon film before and after etching is measured and the etching rate is calculated.

As a result, the positive correlation is observed between the pressure and the etching rate in a pressure range of 20 Pa to 60 Pa as shown in FIG. 5. On the other hand, the etching rate when the pressure is set to 80 Pa is decreased than the etching rate when the pressure is set to 60 Pa. Accordingly, the saturated pressure P_{A} is set to 60 Pa according to the modification example shown in FIG. 4B.

Next, as shown in Step S2 of FIG. 1, a preferable pressure range is determined based on the result of the preliminary experiment. As shown in FIG. 5, the above-described pressure range a1 is set to 51 Pa or more and the pressure range b is set to 30 Pa or less because the etching rate R_{A} is about 530 nm/min at a pressure of 60 Pa and the pressure P_{B} implementing the etching rate (R_{A}/2), that is, the etching rate at 265 nm/min is 30 Pa.

Subsequently, the main process is performed as shown in Step S3 of FIG. 1. Firstly, as shown in FIG. 6A, four silicon wafers 11 are prepared, plural trenches 12 are formed on the upper surface of each silicon wafer 11 and a silicon oxide film 13 is formed on the upper surface of the silicon wafer 11 and the inner surface of the trenches 12. Next, a poly-crystalline silicon film 14 with a thickness of 800 nm is formed by depositing silicon on the entire surface using the CVD method. The poly-crystalline silicon film 14 is also embedded in the trench 12. In this way, four wafers to be evaluated 10 are produced.

Next, as shown in FIG. 6B, the CDE is performed to etch back the poly-crystalline silicon film 14. At this time, a mixed gas of oxygen (O₂) and carbon tetrafluoride (CF₄) is used as the etching gas, and both flow rates of oxygen and carbon tetrafluoride are set to 100 sccm. The output is set to 600 W and the etching time is set to a time in which the etching amount of the silicon film containing impurities is 1.2 μm. Further, the pressures are allowed to be different from one another between four wafers to be evaluated 10 and set to 20 Pa, 40 Pa, 60 Pa, and 80 Pa respectively. In addition, the pressure value of 20 Pa is in the above-described preferable range b, and the pressure value of 40 Pa is not included in the above-described preferable range b or in the above-described preferable range a1, and the pressure values of 60 Pa and 80 Pa are in the above-described preferable range a1.

Samples for observation containing nine trenches 12 are collected from respective three locations of “top”, “center”, and “notch” of the respective wafers to be evaluated 10 as shown in FIG. 7. The above-described “center” is a central portion of the wafer to be evaluated 10, “notch” is an end portion of a side on which a notch is formed and “top” is an end portion which is the opposite side of “notch.”

Next, in regard to the samples for observation, cross-sectional scanning electron microscope (SEM) observation is performed to measure etching depth d in both side portions of the respective trenches 12 as shown in FIG. 6B. Further, the average value, the maximum value, and the minimum value of the etching depth d are calculated for each of the wafers 10 for evaluation. Subsequently, the “variation” is calculated for each of the wafers to be evaluated 10 according to the following expression (1) using the average value, the maximum value, and the minimum value of the etching depth d.

(Variation)=(maximum value−minimum value)/(maximum value+minimum value)×100 (%) (1)

As shown in FIG. 8, the variation was relatively small when the pressures are set to 20 Pa, 60 Pa, and 80 Pa. On the contrary, the variation is relatively large when the pressure is set to 40 Pa. In this way, it is verified that the uniformity of dry etching in the surface of the wafer is improved when the pressure is set to a value in the above-described preferable range a1 or a value in the above-described preferable range b.

According to the embodiment described above, a method of manufacturing a semiconductor device with small variation in shape can be implemented.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, comprising:
dry-etching on a member containing silicon in a first pressure range equal to or more than a first pressure or in a second pressure range equal to or less than a second pressure,
wherein the first pressure is obtained by multiplying a saturated pressure by 0.85, the saturated pressure is defined as a pressure under which an etching rate is one of a maximum value or a value obtained by multiplying the maximum value by a predetermined coefficient, and the etching rate is a half value of the maximum value under the second pressure.

2. The method according to claim 1, wherein the first pressure range is equal to or less than the pressure obtained by multiplying the saturated pressure by 1.15.

3. The method according to claim 1, wherein at least one of oxygen and carbon tetrafluoride is used as an etching gas.

4. The method according to claim 1, wherein the dry-etching is chemical dry etching or reactive ion etching.

5. The method according to claim 1, further comprising:
forming a trench on an upper surface of the member;
forming a silicon oxide film on an inner surface of the trench; and
embedding a poly-crystalline silicon film in the trench, before the dry-etching.

6. The method according to claim 1, wherein the member is one of a silicon wafer, a poly-crystalline silicon film on a silicon wafer, and an amorphous silicon film on a silicon wafer.

7. The method according to claim 1, wherein
the etching rate is increased with increasing a pressure in a measurement range to reach the maximum value under the saturated pressure and continues the maximum value under more than the saturated pressure.

8. The method according to claim 1, wherein
the etching rate is increased with increasing the pressure to reach the maximum value under the saturated pressure and is decreased under more than the saturated pressure.

9. The method according to claim 1, wherein
the etching rate is increased with increasing the pressure to be the maximum value under a maximum pressure in the measurement range, and the saturated pressure is set by multiplying the maximum pressure by the predetermined coefficient.

10. The method according to claim 9, wherein
the predetermined coefficient is set to be 0.95.

11. A method of manufacturing a semiconductor device, comprising:
dry-etching a member containing silicon to be evaluated in a first pressure range equal to or more than a first pressure or in a second pressure range equal to or less than a second pressure, wherein the first pressure is obtained by multiplying a saturated pressure by 0.85, the saturated pressure is defined as a pressure under which an etching rate is one of a maximum value or a value obtained by multiplying the maximum value by a predetermined coefficient, and the etching rate is a half value of the maximum value under the second pressure;
evaluating the member containing silicon to be evaluated to decide a third pressure range; and
dry-etching a member containing silicon to be processed under the third pressure range.

12. The method according to claim 11, wherein
the member containing silicon to be evaluated is one of a silicon wafer, a poly-crystalline silicon film on a silicon wafer, and an amorphous silicon film on a silicon wafer.

13. The method according to claim 11, further comprising:
forming a trench on an upper surface of the member;
forming a silicon oxide film on an inner surface of the trench; and
embedding a silicon film in the trench;
before the dry-etching of the member containing silicon to be evaluated.

14. The method according to claim 13, wherein
an etching depth of the silicon film embedded in the trench is measured as the evaluating.

15. The method according to claim 14, wherein
a variation of the etching depth is evaluated in the evaluating to introduce the third pressure range.
